(19) United States
(12) Patent Application Publication
(10) Pub. No.: US 2010/0072058 A1
(43) Pub. Date: Mar. 25, 2010

(54) PROCESS FOR SURFACE TREATING PLASTIC SUBSTRATE

(75) Inventors: CHWAN-HWA CHIANG, Shindian (TW); BIN ZHANG, Shenzhen City (CN); GANG XIONG, Shenzhen City (CN); FENG-YUEN DAI, Shindian (TW); JENG-SHIUNG CHEN, Shindian (TW)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/536,300

(22) Filed: Aug. 5, 2009

(30) Foreign Application Priority Data
Sep. 19, 2008 (CN) 200810304562.X

(51) Int. Cl. C23C 14/34; B05D 3/00; C23C 14/06

(52) U.S. Cl. 204/192.14; 427/296; 427/530

(57) ABSTRACT

A process for surface treating a plastic substrate is provided. The method includes the steps of providing a plastic substrate; forming a golden-colored vacuum coated layer which is nonconductive on the plastic substrate; and forming a protective coating on the vacuum coated layer. A golden vacuum coated layer which is nonconductive is formed on the plastic substrate by the present process.

### BACKGROUND

1. Technical Field

The present disclosure relates to processes for surface treating a plastic substrate.

2. Description of Related Art

Vacuum coating is widely used for coating casings of electronic devices. Vacuum coating is more environmentally friendly than electroplating. Many casings molded of plastic can be vacuum coated with a glossy metallic surface appearance, and thus attract more consumers.

However, on communication devices, the metallic coatings on the casings using typical vacuum coating process are electrically conductive, which may decrease the quality of communication signals.

Therefore, there is room for improvement within the art.

### DETAILED DESCRIPTION OF THE EXEMPLARY EMBODIMENTS

A process for surface treating a plastic substrate may include the following steps.

In a first step, a plastic substrate is provided.

In a second step, the plastic substrate is pretreated. The pretreatment includes cleaning the substrate to remove oil and dust from the substrate, and ionizing the substrate surface to improve the adhesive force for the subsequent vacuum coated layers.

In a third step, one or more vacuum coated layers of a golden color are formed on the pretreated substrate surface. The vacuum coated layer(s) are nonconductive.

In a fourth step, a protective coating is formed on the surface of the vacuum coated layer. The protective coating may include a middle paint layer and a top paint layer. The middle paint layer is transparent and may be colored or colorless. The middle paint layer may be formed by a ultraviolet curing paint or an ordinary hot curing paint (polyurethane paint and unsaturated polyester paint, e.g. ). The middle paint layer can improve the adhesion of the subsequent top paint layer. The top paint layer is provided with a certain rigidity degree to present a better protecting for the substrate surface. The top paint layer may be made with a transparent ultraviolet curing paint.

It should be understood that the middle paint layer of the protective coating can be omitted, and dyes can be desirably added into the top paint layer.

The following embodiments are intended to illustrate/detail various aspect of the surface treating process as set forth above.

### Embodiment 1

A process for surface treating a plastic substrate may include the following steps.
(1) provide a plastic substrate.
(2) pre-treat the plastic substrate. The pre-treating process may be carried out by degreasing the plastic substrate surface with a cleaning solution containing organic solvent (ethanol and isopropyl alcohol e.g.) to remove oil stains on the plastic substrate; and ionizing the plastic substrate surface by a ion cleaning process to improve the adhesion of the plastic substrate surface, wherein the ion cleaning process can be carried out in a vacuum coating apparatus.
(3) form an aureate titanium nitride coating (TiN) layer on the plastic substrate surface by a vacuum reactive sputtering process or a reactive arc discharge ion plating process, using titanium as the target and nitrogen as the react gas.
(4) paint a transparent middle paint layer on the surface of the titanium nitride coating (TiN) layer. The paint can be selected as ultraviolet curing paint.
(5) paint a transparent top paint layer of ultraviolet curing paint on the middle paint layer.

### Embodiment 2

A process for surface treating a plastic substrate may include the following steps:
(1) provide a plastic substrate.
(2) pre-treat the plastic substrate, during which the plastic substrate surface is degreased by a cleaning solution containing organic solvent (ethanol and isopropyl alcohol e.g.) to remove oil stains on the plastic substrate; and a base coating of ultraviolet curing paint is formed on the plastic substrate. The base coating has a thickness of about 2-30 μm.
(3) form a golden color indium-aluminum alloy coating layer by a vacuum evaporating process using indium and aluminum as the target. The thickness of the indium-aluminum alloy coating layer may be about 100-800 nm. The weight ratio of the indium to the aluminum in the indium-aluminum alloy coating layer may be about 16 to 13.
(4) paint a transparent middle paint layer containing dyes on the indium-aluminum alloy coating layer. The middle paint layer may be a ultraviolet curing paint.
(5) paint a transparent top paint layer on the middle paint layer. The top paint layer is ultraviolet curing paint.

### Embodiment 3

A process for surface treating a plastic substrate may include the following steps.
(1) provide a plastic substrate.
(2) pre-treat the plastic substrate. This pre-treating process may be carried out by a degreasing of the plastic substrate surface using a cleaning solution containing organic solvent (ethanol and isopropyl alcohol e.g.) to remove oil stains on the plastic substrate; and an ionizing of the plastic substrate surface to improve the adhesion force of the plastic substrate surface in a ion cleaning process. The ion cleaning process can be carried out in a vacuum coating apparatus.
(3) form an indium layer on the plastic surface by a vacuum sputtering using indium as the target. The thickness of the indium layer may be about 90-110 nm
(4) form a chromium layer on the indium layer by a vacuum sputtering using chromium as the target. The thickness of the chromium layer may be about 20-40 nm. The chromium layer has a golden color.
(5) form a transparent ultraviolet curing paint on the chromium layer.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A process for surface treating a plastic substrate comprising:
providing a plastic substrate;
forming a golden-colored vacuum coated layer on the substrate surface, the vacuum coated layer being nonconductive; and
forming a protective coating on the vacuum coated layer.

2. The process for surface treating a plastic substrate as claimed in claim 1, wherein the vacuum coated layer is a titanium nitride coating layer.

3. The process for surface treating a plastic substrate as claimed in claim 2, wherein the titanium nitride coating layer is formed by a vacuum reactive sputtering process or a reactive arc discharge ion plating process.

4. The process for surface treating a plastic substrate as claimed in claim 3, further comprising before forming the vacuum coated layer, pre-treating the substrate by degreasing the substrate surface with a cleaning solution containing organic solvent; and ionizing the plastic substrate surface by a ion cleaning process.

5. The process for surface treating a plastic substrate as claimed in claim 1, wherein the vacuum coated layer is an indium-aluminum alloy coating layer.

6. The process for surface treating a plastic substrate as claimed in claim 5, wherein the thickness of the indium-aluminum alloy coating layer is about 100-800 nm, wherein the weight ratio of the indium to the aluminum is from about 16 to about 13.

7. The process for surface treating a plastic substrate as claimed in claim 5, wherein the indium-aluminum alloy coating layer is formed by a vacuum evaporating method.

8. The process for surface treating a plastic substrate as claimed in claim 5, further comprising before forming the indium-aluminum alloy coating layer, pre-treating the substrate by degreasing the substrate using a cleaning solution containing organic solvent; and forming a base coating of ultraviolet curing paint on the substrate.

9. The process for surface treating a plastic substrate as claimed in claim 1, wherein the protective coating includes a transparent middle paint layer and a transparent top paint layer formed on the middle paint layer

10. The process for surface treating a plastic substrate as claimed in claim 9, wherein the middle paint layer is colorized.

11. The process for surface treating a plastic substrate as claimed in claim 1, wherein the protective coating includes a transparent top paint layer.

12. The process for surface treating a plastic substrate as claimed in claim 11, wherein the top paint layer is comprised of ultraviolet curing paint.

13. A process for surface treating a plastic substrate comprising:
providing a plastic substrate;
forming an indium layer on the substrate surface by vacuum sputtering;
forming a chromium layer on the indium layer by vacuum sputtering; and
forming a protective coating on the vacuum coated layer.

14. The process for surface treating a plastic substrate as claimed in claim 13, wherein the indium layer has a thickness of about 90-110 nm.

15. The process for surface treating a plastic substrate as claimed in claim 14, wherein the chromium layer has a thickness of about 20-40 nm.

16. The process for surface treating a plastic substrate as claimed in claim 13, wherein the protective coating includes a transparent middle paint layer and a transparent top paint layer formed on the middle paint layer

17. The process for surface treating a plastic substrate as claimed in claim 16, wherein the middle paint layer is colorized.

18. The process for surface treating a plastic substrate as claimed in claim 13, further comprising before forming the indium layer, pre-treating the substrate by degreasing the substrate surface with a cleaning solution containing organic solvent; and ionizing the plastic substrate surface by a ion cleaning process.
